(19) United States
(12) Patent Application Publication
(10) Pub. No.: US 2017/0255096 A1
(43) Pub. Date: Sep. 7, 2017

(54) PATTERN-FORMING METHOD

(71) Applicant: JSR CORPORATION, Minato-ku (JP)

(72) Inventor: Hitoshi OSAKI, Tokyo (JP)

(73) Assignee: JSR CORPORATION, Minato-ku (JP)

(21) Appl. No.: 15/058,621

(22) Filed: Mar. 2, 2016

(51) Int. Cl. G03F 7/039; G03F 7/16

(52) U.S. Cl. CPC G03F 7/039; G03F 7/16

(57) ABSTRACT

A pattern-forming method enables a resist pattern having a favorable shape with a desired size to be conveniently formed while generation of defects is inhibited, and by using such a superior resist pattern as a mask, a pattern having a favorable shape and arrangement can be formed. The pattern-forming method including: overlaying a base pattern on a front face side of a substrate directly or via other layer; applying a first composition on at least a lateral face of the base pattern; forming a polymer layer by graft polymerization on a surface of the coating film formed after the applying; and etching the substrate by one or a plurality of etching operations by using a resist pattern that includes the base pattern, the coating film and the polymer layer.

### BACKGROUND OF THE INVENTION

### Field of Invention

The present invention relates to a pattern-forming method.

In these days, microfabrication of various types of electronic device structures such as semiconductor devices and liquid crystal devices has been accompanied by demands for miniaturization of patterns in lithography processes. To meet such demands, instead of conventional methods for forming a resist pattern by: using a radiation-sensitive resin composition; and exposing through a mask pattern, methods have been proposed in which a finer pattern is formed by using a phase separation structure formed through directed self-assembly of a block copolymer produced by copolymerization of a first monomer having one property, and a second monomer having a property distinct from that of the first monomer (see, Japanese Unexamined Patent Application, Publication No. 2008-149447, Japanese Unexamined Patent Application (Translation of PCT Application), Publication No. 2002-519728, and Japanese Unexamined Patent Application, Publication No. 2003-218383).

By way of use of any one of such methods, a method has been contemplated in which after a composition containing a block copolymer is applied on a film having a formed hole pattern, a concentrically cylindrical phase separation structure is formed, followed by removing a central phase of the phase separation structure, whereby a contact hole pattern is formed having a hole diameter smaller than that of the hole pattern (see US Patent Application, Publication No. 2010/0297847).

However, according to the method for forming a contact hole pattern, as the formed hole diameter is smaller, the circularity of the holes is impaired, and generation of defects such as covering of the contact holes with the film cannot be inhibited, leading to a disadvantage that from the contact holes, it may be difficult to form contact holes with a favorable shape and arrangement on the substrate by etching, etc. In addition, according to the method in which the directed self-assembly is used, when a pattern with various hole size is to be formed, it is necessary to synthesize and use a block copolymer having blocks with a length corresponding to the size of the pattern to be formed, leading to another disadvantage of complicated operations.

### PRIOR ART DOCUMENTS

### Patent Documents

Patent Document 1: Japanese Unexamined Patent Application, Publication No. 2008-149447

Patent Document 2: Japanese Unexamined Patent Application (Translation of PCT Application), Publication No. 2002-519728

Patent Document 3: Japanese Unexamined Patent Application, Publication No. 2003-218383

Patent Document 4: US Patent Application, Publication No. 2010/0297847

### SUMMARY OF THE INVENTION

The present invention was made in view of the foregoing circumstances, and it is an object of the present invention to provide a pattern-forming method that enables a resist pattern having a favorable shape with a desired size to be conveniently formed while generation of defects is inhibited, and by using such a superior resist pattern as a mask, a pattern having a favorable shape and arrangement can be formed.

According to an aspect of the invention made for solving the aforementioned problems, a pattern-forming method includes the steps of: overlaying a base pattern on the front face side of a substrate directly or via other layer (hereinafter, may be also referred to as “overlaying step”); applying a first composition (hereinafter, may be also referred to as “composition (I)”) on at least the lateral face of the base pattern to form a coating film (hereinafter, may be also referred to as “applying step”); forming a polymer layer by graft polymerization on the surface of the coating film formed after the applying (hereinafter, may be also referred to as “polymer layer-forming step”); and etching the substrate by one or a plurality of etching operations by using a resist pattern that includes the base pattern, the coating film and the polymer layer (hereinafter, may be also referred to as “etching step”).

According to the pattern-forming method of the aspect of the present invention, a resist pattern having a favorable shape with a desired size can be conveniently formed while generation of defects is inhibited, and by using such a superior resist pattern as a mask, a pattern having a favorable shape and arrangement can be formed. Therefore, the pattern-forming method can be suitably used for working processes of semiconductor devices, and the like, in which microfabrication is expected to be further in progress hereafter.

### BRIEF DESCRIPTION OF THE DRAWINGS

FIG. 1 shows a schematic cross sectional view illustrating one example of the state after forming a base pattern on the front face side of a substrate;

FIG. 2 shows a schematic cross sectional view illustrating one example of the state after applying the composition (I) on the lateral face of the base pattern shown in FIG. 1;

FIG. 3 shows a schematic cross sectional view illustrating one example of the state after forming a polymer layer by graft polymerization on the surface of the coating film formed as shown in FIG. 2;

FIG. 4 shows an electron micrograph illustrating one example of a film defect; and

FIG. 5 shows an electron micrograph illustrating one example of a film defect.

### DESCRIPTION OF THE EMBODIMENTS

### Pattern-Forming Method

The pattern-forming method includes the overlaying step, the applying step, the polymer layer-forming step, and the etching step. According to the pattern-forming method, due to including each step described above, and also due to adopting the resist pattern-forming method in which the polymer layer is formed by graft polymerization on the surface of the coating film formed by applying the composition (I) on at least the lateral face of the base pattern, a resist pattern having a desired size and a favorable shape such as circularity can be conveniently formed while generation of defects is inhibited. In addition, by using such a superior resist pattern as a mask, a pattern having a favorable shape and arrangement can be formed. Hereinafter, each step will be described with reference to drawings.

### Overlaying Step

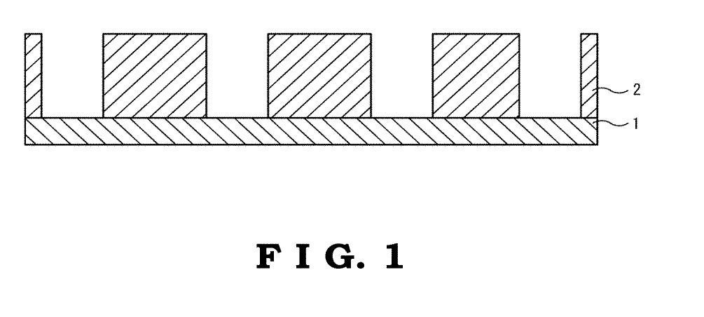

In this step, a base pattern is overlaid on the front face side of a substrate directly or via other layer. The base pattern 2 may be directly formed on one face of a substrate 1 as shown in FIG. 1, or may be formed via other layer by, for example, after forming an underlayer film, a spin-on glass (SOG) film and/or a resist film on the upper face (one side face) of the substrate, and then forming the base pattern 2 on the upper side face (a side face not facing the substrate 1) of these films on the substrate 1. Of these procedures, in light of possible formation of the pattern in a more convenient manner on the substrate by etching using as a mask the base pattern formed, it is preferred that the base pattern is directly formed on one face side of the substrate.

Procedure of Base Pattern Formation

According to an exemplary procedure of directly forming the base pattern 2 on one face of the substrate 1, for example, after directly forming the underlayer film on one face of the substrate 1, a hole pattern is formed on the underlayer film. In this procedure, more specifically, the underlayer film is formed on the upper face side of the substrate 1 by using a composition for underlayer film formation. Next, as needed, an SOG film may be formed on the upper face side of the underlayer film on the substrate 1 by using an SOG composition. The resist film is formed on the upper face of the underlayer film or the SOG film on the substrate 1 by using a resist composition. Then, this resist film is exposed and developed, whereby a resist film pattern is formed. By using this resist film pattern as a mask, the SOG film and/or the underlayer film are/is sequentially etched. The etching procedure may involve dry etching in which a gas mixture of CF₄/O₂/Air, N₂/O₂, etc., is used; wet etching in which an aqueous hydrofluoric acid solution, etc., is used; or the like. Of these, in light of more favorable transfer of the shape to be executed, the dry etching is preferred. When the underlayer film and the SOG film are sequentially dry-etched, it is preferred that the SOG film remaining on the surface of the resulting underlayer film pattern is detached away by using an aqueous hydrofluoric acid solution or the like. Accordingly, the base pattern 2 directly formed on one face of the substrate 1 is obtained.

As the substrate 1, a conventionally well-known substrate such as, for example, a silicon (Bare-Si) wafer, a wafer coated with aluminum may be used.

As the composition for underlayer film formation, a conventionally well-known organic underlayer film-forming material or the like may be used, and for example, a composition for underlayer film formation containing a crosslinking agent and the like may be exemplified.

The forming procedure of the underlayer film is not particularly limited, and, for example, a process in which after applying a composition for underlayer film formation on one face of the substrate by a well-known procedure such as spin coating, followed by prebaking (PB), the resultant coating film is hardened by carrying out irradiation with a radioactive ray and/or heating, and the like may be exemplified. Examples of the radioactive ray for use in irradiation include: electromagnetic waves such as a visible light ray, an ultraviolet ray, a far ultraviolet ray, an X-ray and a γ-ray; particle rays such as electron beam, a molecular beam and an ion beam; and the like. The lower limit of the temperature of the heating is preferably 90° C., more preferably 120° C., and still more preferably 150° C. The upper limit of the temperature of the heating is preferably 550° C. and more preferably 450° C., and a temperature of no higher than 300° C. is even more preferred. The lower limit of the heating time period is preferably 5 sec, more preferably 10 sec, and still more preferably 20 sec. The upper limit of the heating time period is preferably 1,200 sec, more preferably 600 sec, and still more preferably 300 sec. The lower limit of the average thickness of the underlayer film is preferably 10 nm, more preferably 30 nm, and still more preferably 50 nm. The upper limit of the average thickness is preferably 1,000 nm, more preferably 500 nm, and still more preferably 200 nm.

As the SOG composition, a conventionally well-known SOG composition or the like may be used, and for example, a composition containing organic polysiloxane, and the like may be exemplified.

The forming procedure of the SOG film is not particularly limited, and, for example, a process in which after applying an SOG composition on one face of the substrate or on the face of the underlayer film not facing the substrate 1 by a well-known procedure such as spin coating, followed by PB, the resultant coating film is hardened by carrying out irradiation with a radioactive ray and/or heating, and the like may be exemplified. Examples of the radioactive ray for use in irradiation include: electromagnetic waves such as a visible light ray, an ultraviolet ray, a far ultraviolet ray, an X-ray and a γ-ray; particle rays such as electron beam, a molecular beam and an ion beam; and the like. The lower limit of the temperature of the heating is preferably 100° C., more preferably 150° C., and still more preferably 180° C. The upper limit of the temperature of the heating is preferably 450° C., more preferably 400° C., and still more preferably 350° C. The lower limit of the heating time period is preferably 5 sec, more preferably 10 sec, and still more preferably 20 sec. The upper limit of the heating time period is preferably 1,200 sec, more preferably 600 sec, and still more preferably 300 sec. The lower limit of the Average thickness of the SOG film is preferably 10 nm, more preferably 15 nm, and still more preferably 20 nm. The upper limit of the average thickness is preferably 1,000 nm, more preferably 500 nm, and still more preferably 100 nm.

As the resist composition, for example, a conventional resist composition such as a composition containing a polymer having an acid-labile group, a radiation-sensitive acid generator and a solvent, or the like may be used.

In the procedure of resist film pattern formation, the resist composition is first applied on: one face of the substrate 1; a face of the underlayer film not facing the substrate 1; or a face of the SOG film not facing the substrate 1, and thereafter prebaking (PB) is carried out, whereby a resist film is formed. Next, an exposure is carried out through a mask pattern for forming the base pattern 2 having a desired shape. Examples of the radioactive ray which may be used for the exposure include electromagnetic waves such as an ultraviolet ray, a far ultraviolet ray, an extreme ultraviolet ray (EUV), and an X-ray; charged particle rays such as an electron beam and an a-ray, and the like. Of these, the far ultraviolet ray is preferred, an ArF excimer laser beam and a KrF excimer laser are more preferred, and an ArF excimer laser beam is still more preferred. For the exposure, liquid immersion lithography may be employed. After the exposure, it is preferred that post exposure baking (PEB) is carried out. Then, a development is carried out by using a developer solution, e.g., an alkaline developer solution such as a 2.38% by mass aqueous tetramethylammonium hydroxide solution or an aqueous tetrabutylammonium hydroxide solution, an organic solvent such as butyl acetate or anisole.

The lower limit of the average thickness of the resist film is preferably 10 nm, more preferably 30 nm, and still more preferably 50 nm. The upper limit of the average thickness is preferably 1,000 nm, more preferably 500 nm, and still more preferably 200 nm.

The shape of the base pattern 2 may be appropriately selected depending on the shape of the formed pattern that the substrate will finally have, and is exemplified by: circular such as true circular and elliptic; polygonal e.g., quadrilateral such as regular tetragonal, rectangular and trapezoidal, triangular such as regular triangular and isosceles triangular; and the like. Of these, in light of the possibility of more conveniently forming the contact hole pattern, the shape of the formed pattern is preferably circular, and more preferably true circular.

The lower limit of the average diameter of the base pattern 2 to be formed is preferably 10 nm, more preferably 20 nm, still more preferably 30 nm, and particularly preferably 40 nm. The upper limit of the average diameter is preferably 200 nm, more preferably 100 nm, still more preferably 90 nm, and particularly preferably 80 nm.

The lower limit of the pitch of the base pattern 2 formed is preferably 30 nm, more preferably 60 nm, even more preferably 100 nm, and particularly preferably 150 nm. The upper limit of the pitch is preferably 1,000 nm, more preferably 500 nm, even more preferably 300 nm, and particularly preferably 250 nm.

The lower limit of the ratio of the pitch to the average diameter of the base pattern 2 is preferably 0.5, more preferably 1, even more preferably 1.5, and particularly preferably 2. The upper limit of the ratio is preferably 10, more preferably 7, even more preferably 5, and particularly preferably 4.

Thus obtained base pattern 2 is preferably subjected to a treatment of, for example, irradiating with an ultraviolet ray of 254 nm, etc., followed by heating at 100° C. or higher and 200° C. or lower for a time period of no less than 1 min and no greater than 30 min so as to promote hardening.

In addition, the face of the base pattern 2 may be subjected to a hydrophobilization treatment or a hydrophilization treatment. A specific treatment procedure may be exemplified by e.g., a hydrogenation treatment including an exposure to hydrogen plasma for a certain period of time. By increasing the hydrophobicity or hydrophilicity of the face of the base pattern 2, application properties of the composition (I) in the applying step can be more improved.

### Applying Step

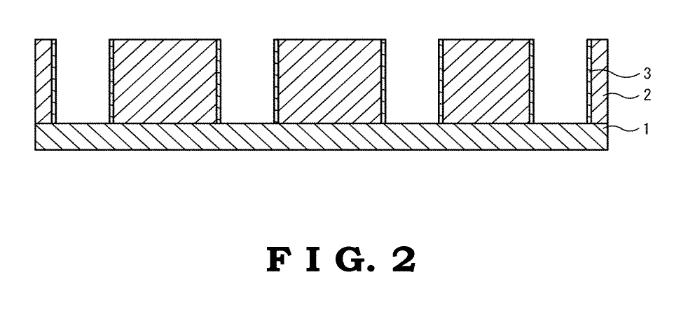

In this step, the composition (I) is applied on at least the lateral face of the base pattern 2. Accordingly, a coating film 3 is formed on at least the lateral face of the base pattern 2 as shown in FIG. 2.

The applying procedure of the composition (I) is exemplified by spin coating and the like. After the applying, PB, etc., may be carried out to remove the solvent and the like, whereby the coating film 3 is formed on the face of the base pattern 2.

It is preferred that the substrate 1 having the coating film 3 formed thereon is heated (baked). By heating the substrate 1 having the coating film 3 formed thereon, the adhesiveness between the base pattern 2 and the coating film 3 can be more improved. The heating means may be exemplified by an oven, a hot plate and the like. The lower limit of the temperature of the heating is preferably 80° C., more preferably 100° C., and still more preferably 150° C. The upper limit of the temperature of the heating is preferably 400° C., more preferably 350° C., and still more preferably 300° C. The lower limit of the heating time period is preferably 10 sec, more preferably 1 min, and still more preferably 5 min. The upper limit of the heating time period is preferably 120 min, more preferably 60 min, and still more preferably 30 min.

After the forming of the coating film 3, the substrate 1 having the coating film 3 formed thereon is preferably washed (rinsed) with a solvent to remove unreacted materials. The solvent for use in washing is exemplified by propylene glycol monomethyl ether acetate, and the like.

Composition (I)

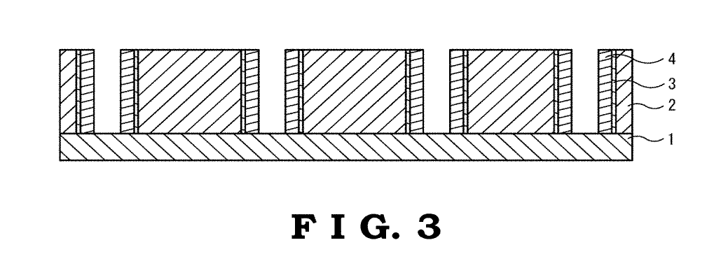

The composition (I) applied in the applying step is not particularly limited as long as a polymer layer 4 can be formed on the surface of the coating film 3 by graft polymerization as shown in FIG. 3, and for example, a composition containing a polymer (hereinafter, may be also referred to as “(A) polymer” or “polymer (A)”), and a solvent (hereinafter, may be also referred to as “(B) solvent” or “solvent (B)”), or the like may be used. The composition (I) may contain other component(s) in addition to the polymer (A) and the solvent (B).

In regard to the polymer (A), after a polymerization active species such as a radical, a cation or an anion is generated on the polymer chain thereof present on the surface of the coating film 3, a monomer is polymerized by means of the polymerization active species, whereby graft polymerization (hereinafter, may be also referred to as “surface graft polymerization”) can be executed.

The term “surface graft polymerization” as referred to means polymerization carried out by giving an active species on a polymer chain present on the surface of a coating film, and further polymerizing other monomer that initiates polymerization by means of the active species, thereby forming a graft polymer.

In a case in which the polymer (A) is formed by living polymerization such as living radical polymerization or living anionic polymerization, by bringing the polymer (A) into contact with the monomer at an appropriate temperature, the polymer (A) reacts with the monomer to permit polymerization, whereby surface graft polymerization can be executed.

The living radical polymerization which may be used in the surface graft polymerization is exemplified by Reversible Addition Fragmentation Chain Transfer polymerization (RAFT polymerization), Atom Transfer Radical polymerization (ATRP), Nitroxide-Mediated Polymerization (NMP), and the like.

RAFT Polymerization

In a case in which the surface graft polymerization is RAFT polymerization, the polymer (A) is exemplified by a polymer having a group that bonds to one end of the main chain thereof and is derived from a compound represented by the following formula (1) (hereinafter, may be also referred to as “compound (I)”), and the like.

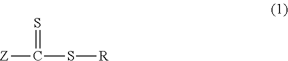

In the above formula (1), Z represents a hydrogen atom, a halogen atom or a monovalent organic group having 1 to 20 carbon atoms; and R represents a substituted or unsubstituted monovalent hydrocarbon group having 1 to 20 carbon atoms.

The “organic group” as referred to means a group that includes at least one carbon atom.

The monovalent organic group having 1 to 20 carbon atoms which may be represented by Z is exemplified by: a monovalent hydrocarbon group having 1 to 20 carbon atoms; a group (a) derived from this hydrocarbon group by including a divalent hetero atom-containing group between two adjacent carbon atoms or at the end on the atomic bonding side; a group derived from the hydrocarbon group and the group (a) by substituting a part or all of hydrogen atoms included therein with a monovalent hetero atom-containing group; and the like.

The monovalent organic group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

The monovalent hydrocarbon group having 1 to 20 carbon atoms is exemplified by a monovalent chain hydrocarbon group having 1 to 20 carbon atoms, monovalent alicyclic hydrocarbon group having 3 to 20 carbon atoms, monovalent aromatic hydrocarbon group having 6 to 20 carbon atoms, and the like.

Examples of the monovalent chain hydrocarbon group having 1 to 20 carbon atoms include:

alkyl groups such as a methyl group, an ethyl group, a propyl group and a butyl group;

alkenyl groups such as an ethenyl group, a propenyl group and a butenyl group;

alkynyl groups such as an ethynyl group, a propynyl group and a butynyl group; and the like.

Examples of the monovalent alicyclic hydrocarbon group having 3 to 20 carbon atoms include:

cycloalkyl groups such as a cyclopropyl group, a cyclopentyl group, a cyclohexyl group, a norbornyl group and an adamantyl group;

cycloalkenyl groups such as a cyclopropenyl group, a cyclopentenyl group, a cyclohexenyl group and a norbornenyl group; and the like.

Examples of the monovalent aromatic hydrocarbon group having 6 to 20 carbon atoms include:

aryl groups such as a phenyl group, a tolyl group, a xylyl group, a naphthyl group and an anthryl group;

aralkyl groups such as a benzyl group, a phenethyl group and a naphthylmethyl group; and the like.

The monovalent and divalent hetero atom-containing groups as referred to mean groups having a hetero atom(s) having a valency of at least 2 in the structure thereof. The hetero atom-containing group may have one hetero atom, or two or more hetero atoms.

The hetero atom having a valency of at least 2 included in the hetero atom-containing group is not particularly limited as long as it is a hetero atom having valency of at least 2, and examples of the hetero atom include an oxygen atom, a nitrogen atom, a sulfur atom, a silicon atom, a phosphorus atom, a boron atom and the like.

Examples of the divalent hetero atom-containing group include:

groups consisting only of hetero atom(s) such as —S—, —SO—, —SO₂—, —SO₂O— and —O—;

groups obtained by combining a carbon atom with a hetero atom(s) such as —CO—, —COO—, —COS—, —CONH—, —OCOO—, —OCOS—, —OCONH—, —SCONH—, —SCSNH—, —SCSS—, and —NR′— (wherein, R′ represents a hydrogen atom or a monovalent hydrocarbon group having 1 to 20 carbon atoms) ; and the like.

Examples of the monovalent hetero atom-containing group include halogen atoms, a hydroxy group, a carboxy group, a nitro group, a cyano group, and the like.

Z represents preferably a monovalent organic group having 1 to 20 carbon atoms, and preferably monovalent hydrocarbon group having 1 to 20 carbon atoms and preferably a group derived from the hydrocarbon group by including —S—, —NR′— (wherein, R′ represents a hydrogen atom or a monovalent hydrocarbon group having 1 to 20 carbon atoms) or —O— at the end on the atomic bonding side.

Z is exemplified by groups represented by the following formulae (Z-1) to (Z-4) (hereinafter, may be also referred to as “groups (Z-1) to (Z-4)”), and the like.

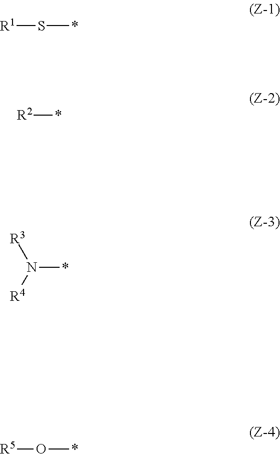

In the above formulae (Z-1) to (Z-4), * denotes a site bonded to the carbon atom of —C(═S)— in the above formula (1).

In the above formula (Z-1), R¹ represents an alkyl group having 1 to 20 carbon atoms.

In the above formula (Z-2), R² represents a substituted or unsubstituted monovalent hydrocarbon group having 1 to 20 carbon atoms.

In the above formula (Z-3), R³ represents an alkyl group having 1 to 20 carbon atoms; and R⁴ represents an aryl group having 6 to 20 carbon atoms.

In the above formula (Z-4), R⁵ represents an alkyl group having 1 to 20 carbon atoms.

Examples of the alkyl group having 1 to 20 carbon atoms represented by R¹, R³ and R⁵ include groups similar to those exemplified as the alkyl group having 1 to 20 carbon atoms which may be represented by Z described above, and the like. Examples of the substituted or unsubstituted monovalent hydrocarbon group having 1 to 20 carbon atoms represented by R² include groups similar to those exemplified as the substituted or unsubstituted hydrocarbon group having 1 to 20 carbon atoms which may be represented by Z described above, and the like. Examples of the aryl group having 6 to 20 carbon atoms represented by R⁴ include groups similar to those exemplified as the aryl group having 6 to 20 carbon atoms which may be represented by Z described above, and the like.

Of these, Z represents preferably the group (Z-1). An n-dodecylsulfanyl group is more preferred.

Examples of the monovalent hydrocarbon group having 1 to 20 carbon atoms represented by R include groups similar to those exemplified as the monovalent hydrocarbon group having 1 to 20 carbon atoms which may be represented by Z described above, and the like.

Examples of the substituent for the monovalent hydrocarbon group include halogen atoms, a hydroxy group, a carboxy group, a nitro group, a cyano group, alkoxycarbonyl groups, and the like. Of these, the carboxy group, the cyano group and the alkoxycarbonyl group are preferred, the cyano group and the alkoxycarbonyl group are more preferred, and the cyano group and a methoxycarbonyl group are still more preferred.

R represents preferably the monovalent hydrocarbon group substituted with a cyano group, a carboxy group and/or an alkoxycarbonyl group, more preferably the monovalent hydrocarbon group substituted with a cyano group and/or an alkoxycarbonyl group, even more preferably the monovalent hydrocarbon group substituted with a cyano group and an alkoxycarbonyl group, and particularly preferably an alkyl group substituted with a cyano group and a methoxycarbonyl group.

Examples of R include groups represented by the following formulae (R-1) to (R-4) (hereinafter, may be also referred to as “groups (R-1) to (R-4)”), and the like.

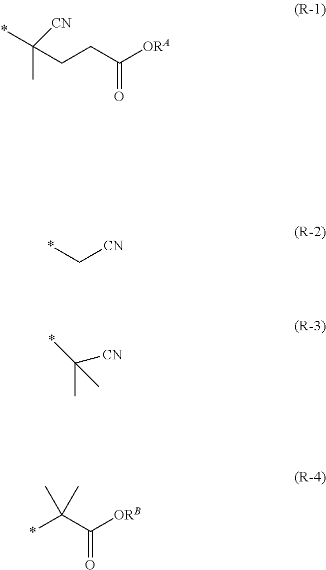

In the above formulae (R-1) to (R-4), * denotes a site bonded to —S— in the above formula (1).

In the above formula (R-1), R^{A} represents a hydrogen atom or a monovalent hydrocarbon group having 1 to 20 carbon atoms.

In the above formula (R-4), R^{B} represents a hydrogen atom or a monovalent hydrocarbon group having 1 to 20 carbon atoms.

Examples of the monovalent hydrocarbon group having 1 to 20 carbon atoms which may be represented by R^{A} and R^{B} include groups similar to those exemplified as the monovalent hydrocarbon group having 1 to 20 carbon atoms which may be represented by Z described above, and the like.

Of these, R represents preferably the group (R-1), and more preferably the group (R-1) in which R^{A} represents a methyl group (4-cyano-1-methoxycarbonylbutan-4-yl group).

Examples of the compound (I) include compounds represented by the following formulae (1-1) to (1-8) (hereinafter, may be also referred to as “compounds (I-1) to (I-8)”), and the like.

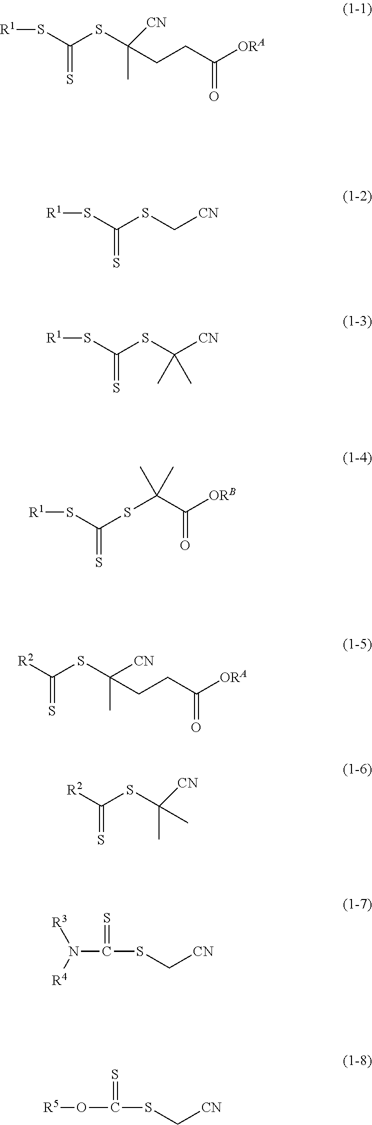

In the above formulae (1-1) to (1-8), R¹ is as defined in the above formula (Z-1); R² is as defined in the above formula (Z-2); R³ and R⁴ are as defined in the above formula (Z-3); R⁵ is as defined in the above formula (Z-4); R^{A} is as defined in the above formula (R-1); and R^{B} is as defined in the above formula (R-4).

Of these, the compound (I) is preferably the compound (I-1).

A reaction scheme of the RAFT polymerization is shown below. It is believed that: the initiator radical I. generated from a polymerization initiator would lead to polymerization of the monomer to produce a polymer chain radical Pm.; and the compound (I) would react with the polymer chain radical Pm., thereby giving a polymer represented by the following formula (P-1), the polymer having a group that bonds to one end of the main chain and is derived from the above formula (1). The polymer (P-1) is, as shown in the scheme below, degraded in the following polymer layer-forming step, into Pm—S—C(═S)—Z and the R.radical. After the R.radical reacts with the monomer added, the product again reacts with Pm—S—C(═S)—Z, thereby producing a polymer represented by the following formula (P-2).

By thus using as the polymer (A), the polymer (P-1) formed by the RAFT polymerization, the reaction with the monomer elongates the polymer chain by living radical polymerization (RAFT polymerization), whereby the polymer layer is formed.

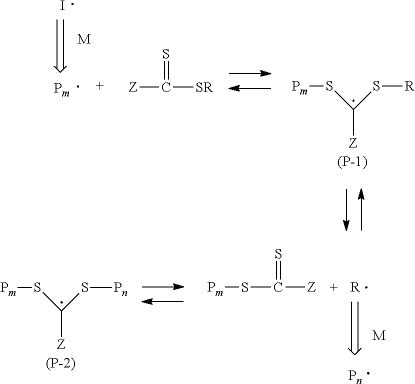

In the above scheme, I. represents an initiator radical; M represents a monomer; Pm. represents a polymer chain radical; Z and R are as defined in the above formula (1); Pm represents a polymer chain; R. represents a radical; Pm. represents a polymer chain radical; and Pn represents a polymer chain.

ATRP

In a case in which the surface graft polymerization is the ATRP, the polymer (A) is exemplified by a polymer having a group that bonds to one end of the main chain thereof and is derived from a compound represented by the following formula (2-1) or (2-2) (hereinafter, may be also referred to as “compound (II-1) or (II-2)”), and the like.

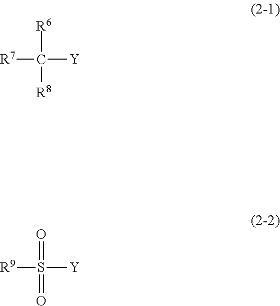

In the above formulae (2-1) and (2-2), Y each independently represents a halogen atom.

In the above formula (2-1), R⁶ and R⁷ each independently represent an alkyl group having 1 to 20 carbon atoms; and R⁸ represents a monovalent organic group having 1 to 20 carbon atoms.

In the above formula (2-2), R⁹ represents a monovalent organic group having 1 to 20 carbon atoms.

Examples of the halogen atom represented by Y include a fluorine atom, a chlorine atom, a bromine atom, an iodine atom, and the like. Of these, in light of the ATRP to occur efficiently, the bromine atom and the iodine atom are preferred, and the iodine atom is more preferred.

Examples of the alkyl group having 1 to 20 carbon atoms represented by R⁶ and R⁷ include the groups similar to those exemplified as the alkyl group having 1 to 20 carbon atoms which may be represented by Z described above, and the like. Examples of the monovalent organic group having 1 to 20 carbon atoms represented by R⁸ and R⁹ include groups similar to those exemplified as the monovalent organic group having 1 to 20 carbon atoms which may be represented by Z, and the like.

R⁶ and R⁷ in the compound (II-1) each represent preferably an alkyl group having 1 to 4 carbon atoms, and more preferably a methyl group. R⁸ represents preferably an aryl group or an alkoxycarbonyl group, more preferably a phenyl group or an ethoxycarbonyl group, and still more preferably a phenyl group.

In the compound (II-2), R⁹ represents preferably an aryl group, and more preferably a phenyl group.

In the ATRP, the compound (II-1), the compound (II-2) and the like may serve as the polymerization initiator, and as needed, in the presence of the compound that provides the halogen atom being Y, such as N-iodosuccinimide, an active species generated by cleavage of a linkage between the halogen atom being Y and an atom adjacent thereto allows the monomer to be polymerized, whereby a polymer is produced having a structure in which the monomer is inserted between the halogen atom being Y and the atom adjacent thereto, the polymer having the group Y that bonds to one end of the main chain thereof and is derived from the compound (II-1) or (II-2).

By thus using as the polymer (A), the polymer formed by the ATRP, the reaction with the monomer elongates the polymer chain by living radical polymerization (ATRP), whereby the polymer layer is formed.

NMP

In a case in which the surface graft polymerization is the NMP, the polymer (A) is exemplified by a polymer having a group that bonds to one end of the main chain thereof and is derived from a compound represented by the following formula (3) (hereinafter, may be also referred to as “compound (III)”), and the like.

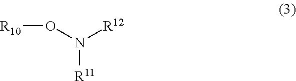

In the above formula (3), R¹⁰, R¹¹ and R¹² each independently represent a substituted or unsubstituted monovalent hydrocarbon group having 1 to 20 carbon atoms.

Examples of the substituted or unsubstituted monovalent hydrocarbon group having 1 to 20 carbon atoms represented by R¹⁰, R¹¹ and R¹² include groups similar to those exemplified as the substituted or unsubstituted monovalent hydrocarbon group having 1 to 20 carbon atoms which may be represented by Z described above, and the like.

R¹⁰ in the compound (III) represents preferably a monovalent aromatic hydrocarbon group, more preferably an aralkyl group, and still more preferably a 1-phenylethan-1-yl group. R¹¹ represents preferably a monovalent chain hydrocarbon group, more preferably an alkyl group, and still more preferably a t-butyl group. R¹² represents preferably a monovalent aromatic hydrocarbon group, more preferably an aralkyl group, and still more preferably a 1-phenyl-2-methylpropan-1-yl group.

In the NMP, the compound (III) and the like may serve as the polymerization initiator, and an active species generated by cleavage of an N—O bond in the nitroxide allows the monomer to be polymerized, whereby a polymer is produced having a structure in which the monomer is inserted in between the N—O bond, the polymer having the group that bonds to one end of the main chain thereof and is derived from the compound (III).

By thus using as the polymer (A), the polymer formed by the NMP, the reaction with the monomer elongates the polymer chain by living radical polymerization (NMP), whereby the polymer layer is formed.

The lower limit of the weight average molecular weight (Mw) of the polymer (A) is preferably 1,000, more preferably 3,000, even more preferably 5,000, and particularly preferably 7,000. The upper limit of the Mw is preferably 100,000, more preferably 50,000, even more preferably 30,000, and particularly preferably 15,000.

The upper limit of the ratio (dispersity index) of the Mw to the number average molecular weight (Mn) of the polymer (A) is preferably 5, more preferably 3, even more preferably 2.5, and particularly preferably 2. The lower limit of the ratio is preferably 1, and more preferably 1.1.

The lower limit of the content of the polymer (A) in the composition (I) with respect to the total solid content is preferably 80% by mass, more preferably 90% by mass, and still more preferably 95% by mass. The upper limit of the content is, for example, 100% by mass. The “total solid content” as referred to means the sum of the components other than the solvent (B).

(B) Solvent

The solvent (B) is not particularly limited as long as it is a solvent capable of dissolving or dispersing at least the polymer (A) and other component(s).

The solvent (B) is exemplified by an alcohol solvent, an ether solvent, a ketone solvent, an amide solvent, an ester solvent, a hydrocarbon solvent, and the like.

Examples of the alcohol solvent include:

monohydric alcohol solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol and diacetone alcohol;

polyhydric alcohol solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol and tripropylene glycol;

polyhydric alcohol partially etherated solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether and dipropylene glycol monopropyl ether; and the like.

Examples of the ether solvent include:

dialkyl ether solvents such as diethyl ether, dipropyl ether and dibutyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone, and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide and N-methylpropionamide; and the like.

Examples of the ester solvent include:

acetic acid ester solvents such as methyl acetate, ethyl acetate, n-propyl acetate, iso-propyl acetate, n-butyl acetate, iso-butyl acetate, sec-butyl acetate, n-pentyl acetate, i-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate and n-nonyl acetate;

polyhydric alcohol partially etherated carboxylate solvents such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monomethyl ether propionate, propylene glycol monoethyl ether acetate, propylene glycol monopropyl ether acetate, propylene glycol monobutyl ether acetate, dipropylene glycol monomethyl ether acetate and dipropylene glycol monoethyl ether acetate;

lactone solvents such as γ-butyrolactone and valerolactone;

carbonate solvents such as dimethyl carbonate, diethyl carbonate, ethylene carbonate and propylene carbonate;

glycol diacetate, methoxytriglycol acetate, ethyl propionate, n-butyl propionate, iso-amyl propionate, diethyl oxalate, di-n-butyl oxalate, methyl acetoacetate, ethyl acetoacetate, methyl lactate, ethyl lactate, n-butyl lactate, n-amyl lactate, diethyl malonate, dimethyl phthalate, and diethyl phthalate; and the like.

Examples of the hydrocarbon solvent include:

aliphatic hydrocarbon solvents such as n-pentane, iso-pentane, n-hexane, iso-hexane, n-heptane, iso-heptane, 2,2,4-trimethylpentane, n-octane, iso-octane, cyclohexane and methylcyclohexane;

aromatic hydrocarbon solvents such as benzene, toluene, xylene, mesitylene, ethylbenzene, trimethylbenzene, methylethylbenzene, n-propylbenzene, iso-propylbenzene, diethylbenzene, iso-butylbenzene, triethylbenzene, di-iso-propylbenzene and n-amylnaphthalene; and the like.

Of these, the ester solvent is preferred, the polyhydric alcohol partially etherated carboxylate solvent is more preferred, and propylene glycol monomethyl ether acetate is still more preferred. The composition (I) may contain one type of the solvent (B), or two or more types thereof.

Other Component

The composition (I) may also contain other component(s) in addition to the polymer (A) and the solvent (B). The other component(s) is/are exemplified by a surfactant and the like. When the composition (I) contains the surfactant, the application property onto the base pattern 2 may be improved.

### Preparation Method of Composition (I)

The composition (I) may be prepared by, for example, mixing the polymer (A), the solvent (B), and as needed the other component(s) at a predetermined ratio, and preferably filtering the resulting mixture through a membrane filter having a polar size of about 200 nm, etc. The lower limit of the solid content concentration of the composition (I) is preferably 0.1% by mass, more preferably 0.5% by mass, and still more preferably 0.7% by mass. The upper limit of the solid content concentration is preferably 30% by mass, more preferably 10% by mass, and still more preferably 5% by mass.

### Polymer Layer-Forming Step

In this step, the surface of the coating film 3 formed after the applying step is subjected to graft polymerization to form the polymer layer 4, as shown in FIG. 3. More specifically, the polymer layer 4 is formed by surface graft polymerization on the surface of the coating film 3. Accordingly, a resist pattern having a size distinct from that of the base pattern 2 is formed.

The average thickness of the polymer layer 4 thus formed may be adjusted to a desired value by appropriately selecting conditions in the surface graft polymerization such as the monomer type, the monomer concentration, the temperature, the time period, etc., whereby a resist pattern with a desired size can be obtained.

In an exemplary procedure for carrying out the surface graft polymerization, e.g., the monomer is brought into contact with the surface of the coating film 3 formed through the applying step at a temperature that allows the surface graft polymerization to proceed, in the presence of as needed, a catalyst, a polymerization initiator, etc. Such a procedure is exemplified by a process in which, for example, the substrate 1 having the coating film 3 formed thereon is immersed in a solution containing the monomer, and as needed, the catalyst, the polymerization initiator, etc.

In a case in which the surface graft polymerization is the living polymerization, by immersing the substrate 1 having the coating film 3 formed thereon into a monomer solution, the surface graft polymerization proceeds, whereby the polymer layer 4 is formed.

The monomer for use in the surface graft polymerization is exemplified by a substituted or unsubstituted styrene, a (meth)acrylic acid ester, a substituted or unsubstituted ethylene (other than those corresponding to the aforementioned substituted or unsubstituted styrene and the aforementioned (meth)acrylic acid ester), and the like.

Examples of the substituted styrene include α-methylstyrene, o-, m- or p-methylstyrene, p-t-butylstyrene, 2,4,6-trimethylstyrene, p-methoxystyrene, p-t-butoxystyrene, o-, m- or p-vinylstyrene, o-, m- or p-hydroxystyrene, m- or p-chloromethylstyrene, p-chlorostyrene, p-bromostyrene, p-iodostyrene, p-nitrostyrene, p-cyanostyrene, and the like.

Examples of the (meth)acrylic acid ester include:

(meth)acrylic acid alkyl esters such as methyl (meth)acrylate, ethyl (meth)acrylate, t-butyl (meth)acrylate and 2-ethylhexyl (meth)acrylate;

(meth)acrylic acid cycloalkyl esters such as cyclopentyl (meth)acrylate, cyclohexyl (meth)acrylate, 1-methylcyclopentyl (meth)acrylate, 2-ethyladamantyl (meth)acrylate and 2-(adamantan-1-yl)propyl (meth)acrylate;

(meth)acrylic acid aryl esters such as phenyl (meth)acrylate and naphthyl (meth)acrylate;

(meth)acrylic acid substituted alkyl esters such as 2-hydroxyethyl (meth)acrylate, 3-hydroxyadamantyl (meth)acrylate, 3-glycidylpropyl (meth)acrylate and 3-trimethylsilylpropyl (meth)acrylate; and the like.

Examples of the substituted ethylene include:

alkenes such as propene, butene and pentene;

vinylcycloalkanes such as vinylcyclopentane and vinylcyclohexane;

cycloalkenes such as cyclopentene and cyclohexene;

4-hydroxy-1-butene, vinyl glycidyl ether, vinyl trimethylsilyl ether, and the like.

Of these, the substituted or unsubstituted styrene is preferred, and the unsubstituted styrene is more preferred.

Examples of the solvent for use in the surface graft polymerization include solvents similar to those exemplified as the solvent (B) in the composition (I), and the like. Of these, the ester solvent is preferred, the polyhydric alcohol partially etherated carboxylate solvent is more preferred, and propylene glycol monomethyl ether acetate is still more preferred. One, or two or more types of these solvents may be used.

The lower limit of the monomer concentration in the monomer solution is preferably 1% by mass, more preferably 5% by mass, even more preferably 10% by mass, and particularly preferably 20% by mass. The upper limit of the monomer concentration is preferably 90% by mass, more preferably 80% by mass, even more preferably 70% by mass, and particularly preferably 60% by mass.

The lower limit of the temperature in the surface graft polymerization is preferably 30° C., more preferably 50° C., even more preferably 70° C., and particularly preferably 90° C. The upper limit of the temperature is preferably 200° C., more preferably 180° C., even more preferably 160° C., and particularly preferably 140° C.

The lower limit of the time period of the surface graft polymerization is preferably 10 min, more preferably 1 hr, even more preferably 3 hrs, and particularly preferably 6 hrs. The upper limit of the time period of the surface graft polymerization is preferably 100 hrs, more preferably 50 hrs, even more preferably 30 hrs, and particularly preferably 25 hrs.

The polymer layer 4 formed is preferably washed (rinsed) with a solvent similar to the solvent used in the surface graft polymerization, or the like.

### Etching Step

In this step, the substrate is etched by one or a plurality of etching operations by using a resist pattern that includes the base pattern, the coating film and the polymer layer. The substrate pattern is formed through this step. The substrate pattern is exemplified by contact holes, and the like. The etching operation is carried out once in a case in which the base pattern 2 was directly formed on the front face side of the substrate 1 in the overlaying step. Whereas, in a case in which the base pattern was formed via other layer on the front face side of the substrate 1, the other layer is etched, and then the other layer after the etching is used as the mask for the etching operations carried out a plurality of times.

The etching procedure is exemplified by well-known techniques including: reactive ion etching (RIE) such as chemical dry etching carried out using CF₄, an O₂ gas or the like by utilizing the difference in etching rate of each phase, etc., as well as chemical wet etching (wet development) carried out by using an etching liquid such as an organic solvent or hydrofluoric acid; physical etching such as sputtering etching and ion beam etching. Of these, the reactive ion etching is preferred, and the chemical dry etching and the chemical wet etching are more preferred.

Prior to the chemical dry etching, an irradiation with a radioactive ray may be also carried out as needed. As the radioactive ray, when the phase to be removed by etching is a methyl polymethacrylate block phase, a radioactive ray of 172 nm or the like may be used. The irradiation with such a radioactive ray results in degradation of the methyl polymethacrylate block phase, whereby the etching is facilitated.

Examples of the organic solvent for use in the chemical wet etching include:

alkanes such as n-pentane, n-hexane and n-heptane;

cycloalkanes such as cyclohexane, cycloheptane and cyclooctane;

saturated carboxylic acid esters such as ethyl acetate, n-butyl acetate, i-butyl acetate and methyl propionate;

ketones such as acetone, methyl ethyl ketone, methyl isobutyl ketone and methyl n-pentyl ketone;

alcohols such as methanol, ethanol, 1-propanol, 2-propanol and 4-methyl-2-pentanol; and the like. These solvents may be used either alone, or two or more types thereof may be used in combination.

After completion of the patterning onto the substrate, the phases used as a mask are removed from the front face side of the substrate by a dissolving treatment or the like, whereby a substrate having the formed pattern can be finally obtained. The substrate obtained according to the pattern-forming method is suitably used for semiconductor elements and the like, and further the semiconductor elements are widely used for LED, solar cells, and the like.

### EXAMPLES

Hereinafter, the present invention is explained in detail by way of Examples, but the present invention is not in any way limited to these Examples. Measuring methods for various types of physical properties are shown below.

### Mw and Mn

The Mw and the Mn of the polymer were determined by gel permeation chromatography (GPC) using GPC columns (Tosoh Corporation; “G2000 HXL”×2, “G3000 HXL”×1 and “G4000 HXL”×1) under the following conditions:

eluent: tetrahydrofuran (Wako Pure Chemical Industries, Ltd.);

flow rate: 1.0 mL/min;

sample concentration: 1.0% by mass;

amount of sample injected: 100 μL;

column temperature: 40° C.;

detector: differential refractometer; and

standard substance: mono-dispersed polystyrene.

### ¹H-NMR Analysis

¹H-NMR analysis was carried out using a nuclear magnetic resonance apparatus (“JNM-EX400” available from JEOL, Ltd.), with DMSO-d₆ for use as a solvent for measurement. The proportion of each structural unit in the polymer was calculated from an area ratio of a peak corresponding to each structural unit on the spectrum obtained by the ¹H-NMR.

### Synthesis of Polymer (A)

### Synthesis Example 1

### Synthesis of Polymer (A-1)

To a 100 mL three-neck flask equipped with a condenser, a dropping funnel and a thermometer were added 4 g of methyl ethyl ketone (MEK), 1.95 g (0.019 mol) of styrene, 0.05 g (0.38 mmol) of 2-hydroxyethyl methacrylate, 0.005 g (0.03 mmol) of azoisobutyronitrile (AIBN) and 0.08 g (0.19 mmol) of methyl 4-cyano-4-[(dodecylsulfanylthiocarbonyl)sulfanyl]pentanoate, and the mixture was stirred under a nitrogen flow at 80° C. for 12 hrs. Thus obtained polymerization reaction mixture was subjected to purification through precipitation in 30 g of methanol such that the polymer was precipitated. The solid was collected on a Buechner funnel, and washed twice with 6 g of methanol. By drying under reduced pressure, 0.85 g of a polymer represented by the following formula (A-1) was obtained as pale yellowish white solid. This polymer (A-1) had the Mn of 9,700, and the Mw/Mn of 1.93.

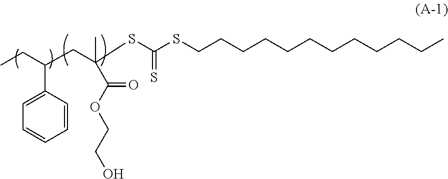

### Synthesis Example 2

### Synthesis of Polymer (A-2)

After a 500 mL flask as a reaction vessel was dried under reduced pressure, 120 g of tetrahydrofuran (THF) which had been subjected to a distillation dehydrating treatment in a nitrogen atmosphere was charged, and cooled to −78° C. Thereafter, 3.10 mL (3.00 mmol) of a 1 N cyclohexane solution of sec-butyllithium (sec-BuLi) was charged into this THF, and then 16.6 mL (0.150 mol) of styrene which had been subjected to: adsorptive filtration by means of silica gel for removing the polymerization inhibitor; and a dehydration treatment by distillation was added dropwise over 30 min. The polymerization system color was ascertained to be orange. During the instillation, the internal temperature of the polymerization reaction mixture was carefully controlled so as not to be −60° C. or higher. After completion of the dropwise addition, aging was permitted for 30 min. Subsequently, a mixture of 1 mL of methanol and 0.63 mL (3.00 mmol) of 2-ethylhexyl glycidyl ether as a chain-end terminator was charged to conduct a terminating reaction of the polymerization end. The temperature of the polymerization reaction mixture was elevated to the room temperature, and the mixture was concentrated. Thereafter, substitution with methyl isobutyl ketone (MIBK) was carried out. Thereafter, 1,000 g of a 2% by mass aqueous oxalic acid solution was charged and the mixture was stirred. After leaving to stand, the aqueous underlayer was removed. This operation was repeated three times to remove the Li salt. Thereafter, 1,000 g of ultra pure water was charged and the mixture was stirred, followed by removing the aqueous underlayer. This operation was repeated three times to remove oxalic acid, and then the resulting solution was concentrated. Subsequently, the concentrate was added dropwise into 500 g of methanol to allow the polymer to be precipitated. The solid was collected on a Buechner funnel. Thus obtained polymer was dried under reduced pressure at 60° C. to give 14.8 g of a polymer represented by the following formula (A-2) as a white solid. This polymer (A-2) had the Mw of 6,100, the Mn of 5,700, and the Mw/Mn of 1.07.

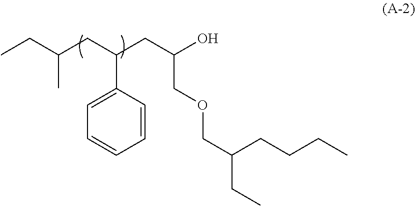

### Synthesis Example 3

### Synthesis of Polymer (A-3)

To a 100 mL three-neck flask equipped with a condenser, a dropping funnel and a thermometer were added 4 g of MEK, 1.95 g (0.019 mol) of styrene, 0.05 g (0.38 mmol) of 2-hydroxyethyl methacrylate, 0.005 g (0.03 mmol) of AIBN, 0.044 g (0.19 mmol) of 1-iodoethylbenzene and 0.0043 g (0.019 mmol) of N-iodosuccinimide, and the mixture was stirred under a nitrogen flow at 80° C. for 12 hrs. Thus obtained polymerization reaction mixture was subjected to purification through precipitation in 30 g of methanol such that the polymer was precipitated. The solid was collected on a Buechner funnel, and washed twice with 6 g of methanol. By drying under reduced pressure, 0.85 g of a polymer represented by the following formula (A-3) was obtained as pale yellowish white solid. This polymer (A-3) had the Mn of 9,200, and the Mw/Mn of 1.43.

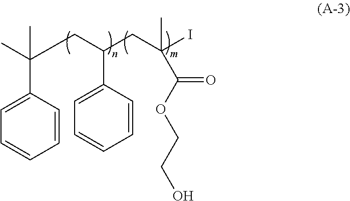

### Synthesis Example 4

### Synthesis of Polymer (A-a)

After a 500 mL flask as a reaction vessel was dried under reduced pressure, 200 g of TI IF which had been subjected to a distillation dehydrating treatment in a nitrogen atmosphere was charged, and cooled to −78° C. Thereafter, 0.46 mL (0.41 mmol) of a 1 N cyclohexane solution of sec-BuLi was added to this THF, and then 13.3 mL (0.115 mol) of styrene which had been subjected to: adsorptive filtration by means of silica gel for removing the polymerization inhibitor; and a dehydration treatment by distillation was added dropwise over 30 min. The polymerization system color was ascertained to be orange. During the instillation, the internal temperature of the polymerization reaction mixture was carefully controlled so as not to be −60° C. or higher. After completion of the dropwise addition, aging was permitted for 30 min. Thereafter, 0.18 mL (0.00124 mol) of 1,1-diphenylethylene, and 1.65 mL (0.0008 mol) of a 0.5 N THF solution of lithium chloride were added thereto, and the polymerization system color was ascertained to be dark red. Furthermore, 11.4 mL (0.108 mol) of methyl methacrylate which had been subjected to: adsorptive filtration by means of silica gel for removing the polymerization inhibitor; and a dehydration treatment by distillation was added dropwise to the polymerization reaction mixture over 30 min. The polymerization system color was ascertained to be light yellow, and thereafter the reaction was allowed to proceed for 120 min. Subsequently, 1 mL of methanol as a chain-end terminator was charged to conduct a terminating reaction of the polymerization end. The temperature of the polymerization reaction mixture was elevated to the room temperature, and the mixture was concentrated. Thereafter, substitution with MIBK was carried out. Thereafter, 1,000 g of a 2% by mass aqueous oxalic acid solution was charged and the mixture was stirred. After leaving to stand, the aqueous underlayer was removed. This operation was repeated three times to remove the Li salt. Thereafter, 1,000 g of ultra pure water was charged and the mixture was stirred, followed by removing the aqueous underlayer. This operation was repeated three times to remove oxalic acid, and the solution was concentrated. Subsequently, the concentrate was added dropwise into 500 g of methanol to allow the polymer to be precipitated. The solid was collected on a Buechner funnel. Next, in order to remove the polystyrene homopolymer, 500 g of cyclohexanone/heptane (mass ratio: 8/2) was poured and the polymer was washed, such that the polystyrene homopolymer was dissolved in cyclohexane/heptane. This operation was repeated four times, and again the solid was collected on a Buechner funnel. Thus obtained polymer was dried under reduced pressure at 60° C. to give 22.5 g of a polymer represented by the following formula (A-a) having white color. This polymer (A-a) has the Mw of 56,200, the Mn of 54,000, and the Mw/Mn of 1.04. In addition, as a result of the ¹H-NMR analysis, the polymer (A-a) was revealed to be a diblock copolymer in which the proportions of the structural unit derived from styrene, and the structural unit derived from methyl methacrylate were 50.2% by mass (49.2 mol %) and 49.8% by mass (50.8 mol %), respectively.

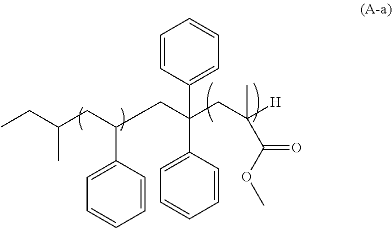

### Preparation of Composition (I)

Components other than the polymer (A) used in the preparation of the composition (I) are shown below.

### (B) Solvent

B-1: propylene glycol monomethyl ether acetate.

### Preparation Example 1

### Preparation of Composition (S-1)

A composition (S-1) was prepared by mixing 100 parts by mass of (A-1) as the polymer (A) and 9,900 parts by mass of (B-1) as the solvent (B), and then filtering the mixed solution thus obtained through a membrane filter having a pore size of 200 nm.

### Preparation Example 2

### Preparation of Composition (S-2)

A composition (S-2) was prepared by mixing 100 parts by mass of (A-2) as the polymer (A) and 9,900 parts by mass of (B-1) as the solvent (B), and then filtering the mixed solution thus obtained through a membrane filter having a pore size of 200 nm.

### Preparation Example 3

### Preparation of Composition (S-a)

A composition (S-a) was prepared by mixing 100 parts by mass of (A-a) as the polymer (A) and 4,900 parts by mass of (B-1) as the solvent (B), and then filtering the mixed solution thus obtained through a membrane filter having a pore size of 200 nm.

### Preparation Example 4

### Preparation of Composition (S-3)

A composition (S-3) was prepared by mixing 100 parts by mass of (A-3) as the polymer (A) and 4,900 parts by mass of (B-1) as the solvent (B), and then filtering the mixed solution thus obtained through a membrane filter having a pore size of 200 nm.

### Base Pattern Formation

An underlayer film having an average thickness of 85 nm was formed on a bare-Si substrate by using a composition for underlayer film formation (“HM710” available from JSR Corporation), and on this underlayer film, an SOG film having an average thickness of 30 nm was formed by using an SOG composition (“ISX302” available from JSR Corporation). On the substrate thus obtained having the underlayer film and the SOG film formed thereon, a positive type resist composition (“AIM5484JN” available from JSR Corporation) was applied to form a resist film having an average thickness of 85 nm, which was then subjected to ArF liquid immersion lithography. The resist film was developed using a 2.38% by mass aqueous tetramethylammonium hydroxide solution to form a resist pattern. Next, by using this resist pattern as a mask, etching of the SOG film was carried out with a gas mixture of CF₄/O₂/Air. Then, the underlayer film was etched by using thus obtained SOG film pattern as a mask with an N₂/O₂ gas mixture. Furthermore, the SOG film left on the surface layer of the obtained underlayer film pattern was detached by using a diluted solution of hydrofluoric acid, whereby a base pattern was formed such that the underlayer film has a hole pattern with a hole size of 60 nm and a pitch of 200 nm.

### Resist Pattern Formation

### Examples 1 to 8

The composition (S-1) prepared as described above was spin-coated by using a track (“DSA ACT12” available from Tokyo Electron Limited), at 1,500 rpm on the base pattern having a hole size of 60 nm and a pitch of 200 nm, followed by baking at 200° C. for 20 min. Then the baked substrate was rinsed with propylene glycol monomethyl ether acetate (PGMEA) to remove unreacted materials and the like. Thus rinsed substrate was immersed into a propylene glycol monomethyl ether solution of styrene under a condition shown in Table 1, and thereafter the substrate was rinsed with PGMEA, whereby a contact hole resist pattern was formed.

### Example 9

In a similar manner to Example 1 except that the composition (S-3) was used in place of the composition (S-1), a contact hole resist pattern was formed.

### Comparative Example 1

The composition (S-2) prepared as described above was spin-coated by using a track (“DSA ACT12” available from Tokyo Electron Limited), at 1,500 rpm on the base pattern having a hole size of 60 nm and a pitch of 200 nm, followed by baking at 200° C. for 20 min. Then the baked substrate was rinsed with propylene glycol monomethyl ether acetate (PGMEA) to remove unreacted materials and the like. The composition (S-a) prepared as described above was spin-coated at 1,500 rpm on the rinsed substrate. This substrate was subjected to heat annealing at 220° C. for 20 min to permit phase separation. The substrate subjected to the phase separation was etched with oxygen plasma to remove the phase formed from the poly(methyl methacrylate) block in the polymer (A-a), whereby a contact hole resist pattern was formed.

### Evaluations

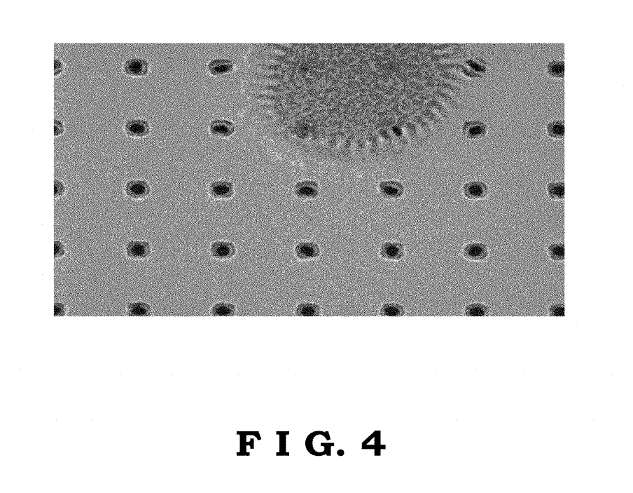

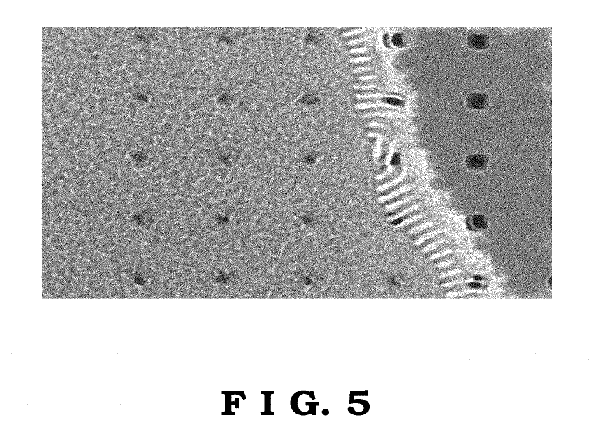

On the resist pattern formed as described above, a highly magnified (100 K) image was taken by using a scanning electron microscope (“Leo1550-2172”, available from Carl Zeiss). The image thus obtained was analyzed using Matlab program, whereby the diameter (CD) and the circularity of each contact hole of the pattern were evaluated. Average diameter was calculated from the CD of each hole pattern obtained, and the amount of change in CD after the process as compared with before the process (shrinkage) was determined. The circularity is defined as a ratio of the distance between elliptic focal points to the elliptic longitudinal diameter. The circularity more closer to 0 means that the shape is approximate to a perfect circle, leading to a determination that the shape is suitable. In addition, the obtained image was used for visual inspection as to the presence or absence of defects that any pattern other than the contact hole pattern covers the contact hole pattern (film defect (shown in FIGS. 4 and 5)). The evaluation was made to be: “A” (favorable) when the presence of the defect was not confirmed, or “B” (unfavorable) when the presence of the defect was confirmed. The results of the evaluations are shown in Table 1.

TABLE 1

| | Immersion conditions | | | | | |
|---|---|---|---|---|---|---|
| | Styrene | Oil bath | Immersion | 200 nm P 60 nm CD | | |
| | concentration | temperature | time period | Shrinkage | | Film |
| | (% by mass) | (° C.) | (hr) | (nm) | Circularity | defect |
| Example 1 | 33 | 85 | 8 | 18 | 0.45 | A |
| Example 2 | 33 | 85 | 18 | 25 | 0.47 | A |
| Example 3 | 33 | 85 | 24 | 30 | 0.39 | A |
| Example 4 | 33 | 85 | 27 | 34 | 0.41 | A |
| Example 5 | 50 | 120 | 3 | 27 | 0.37 | A |
| Example 6 | 67 | 145 | 1 | 26 | 0.38 | A |
| Example 7 | 50 | 100 | 10 | 30 | 0.35 | A |
| Example 8 | 67 | 100 | 10 | 32 | 0.37 | A |
| Example 9 | 33 | 100 | 10 | 30 | 0.25 | A |
| Comparative | — | — | — | 29 | 0.64 | B |
| Example 1 | | | | | | |

### INDUSTRIAL APPLICABILITY

The pattern-forming method according to the embodiment of the present invention enables a resist pattern having a favorable shape with a desired size to be conveniently formed while generation of defects is inhibited, and by using such a superior resist pattern as a mask, a pattern having a favorable shape and arrangement can be formed. Therefore, the pattern-forming method can be suitably used for working processes of semiconductor devices, and the like, in which microfabrication is expected be further in progress hereafter.

### EXPLANATIONS OF THE REFERENCE SYMBOLS

1 substrate

2 base pattern

3 coating film

4 polymer layer

1. A pattern-forming method comprising:
overlaying a base pattern on a front face side of a substrate directly or via other layer;
applying a first composition on at least a lateral face of the base pattern to form a coating film comprising a polymer and attached to the lateral face of the base pattern, a surface of the coating film opposite to the lateral face of the base pattern is exposed to an outside atmosphere;
contacting a second composition comprising a monomer with the coating film;
polymerizing the monomer of the second composition by graft polymerization which starts on a chain of the polymer of the coating film to form a polymer layer on the coating film, such that a resist pattern comprising the base pattern, the coating film and the polymer layer is formed on the front face side of the substrate; and
etching the substrate by one or a plurality of etching operations by using the resist pattern as a mask.

2. The pattern-forming method according to claim 1, wherein
the first composition comprises:
a polymer comprising a group that bonds to one end of a main chain thereof, and is derived from a compound represented by formula (1); and
a solvent, 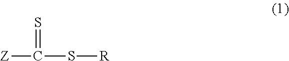
wherein, in the formula (1), Z represents a hydrogen atom, a halogen atom or a monovalent organic group having 1 to 20 carbon atoms; and R represents a substituted or unsubstituted monovalent hydrocarbon group having 1 to 20 carbon atoms.

3. The pattern-forming method according to claim 1, wherein the graft polymerization is Reversible Addition Fragmentation Chain Transfer (RAFT) polymerization.

4. The pattern-forming method according to claim 1, wherein the base pattern is a hole pattern.

5. The pattern-forming method according to claim 1, wherein the first composition comprises a polymer formed by living polymerization, and the forming of the polymer layer was conducted by bringing the polymer into contact with a monomer in a solvent.

6. The pattern-forming method according to claim 5, wherein the monomer is at least one selected from the group consisting of a substituted or unsubstituted styrene, a (meth)acrylic acid ester, and a substituted or unsubstituted ethylene which is other than the substituted or unsubstituted styrene or the (meth)acrylic acid ester.

7. The pattern-forming method according to claim 5, wherein the monomer is a substituted or unsubstituted styrene.

8. The pattern-forming method according to claim 2, wherein the graft polymerization is Reversible Addition Fragmentation Chain Transfer (RAFT) polymerization.

9. The pattern-forming method according to claim 2, wherein the base pattern is a hole pattern.

10. The pattern-forming method according to claim 2, wherein the polymer is formed by living polymerization, and the forming of the polymer layer was conducted by bringing the polymer into contact with a monomer in a solvent.

11. The pattern-forming method according to claim 10, wherein the monomer is at least one selected from the group consisting of a substituted or unsubstituted styrene, a (meth)acrylic acid ester, and a substituted or unsubstituted ethylene which is other than the substituted or unsubstituted styrene or the (meth)acrylic acid ester.

12. The pattern-forming method according to claim 10, wherein the monomer is a substituted or unsubstituted styrene.

13. The pattern-forming method according to claim 1, wherein the polymer layer is formed such that a width of a gap or a hole opening size of the resist pattern is smaller than a width of a gap or a hole opening size of the base pattern.
